(19) United States
(12) Patent Application Publication
(10) Pub. No.: US 2006/0273838 A1
(43) Pub. Date: Dec. 7, 2006

(54) Master latch circuit with signal level displacement for a dynamic flip flop

(75) Inventors: Jorg Berthold, Munich (DE); Georg Jeorgakos, Fraunberg (DE); Stephan Henzler, Munich (DE); Doris Schmitt-Landsiedel, Ottobrunn (DE)

Correspondence Address: MAGINOT, MOOR & BECK, 111 MONUMENT CIRCLE, SUITE 3000, BANK ONE CENTER/TOWER, INDIANAPOLIS, IN, 46204, US

(73) Assignee: INFINEON TECHNOLOGIES AG, Munchen (DE)

(21) Appl. No.: 10/563,040

(22) PCT Filed: Sep. 3, 2004
(86) PCT No.: PCT/EP04/09853

§ 371 Date: Jul. 17, 2006

(30) Foreign Application Priority Data
Sep. 19, 2003 (DE) 103 43 565.4

(51) Int. Cl. H03H 11/26

(52) U.S. Cl. 327/261; 327/211

(57) ABSTRACT

A master latch circuit (10) with signal level displacement for a flip-flop (1) clocked by a clock pulse signal (Clk), wherein the master latch circuit (10) comprises a signal delay circuit (13) which delays and inverts the clock pulse signal (ClK) resulting in a specific time delay (AT), and a circuit node (14) which, in a charging phase wherein the clock pulse signal (Clk) is logically low, is charged to an operational voltage (VB) an which, in an evaluation phase when the clock pulse signal (Clk) and delayed, inverted clock pulse signal (Clk<SB>DELAY</SB>) are logically high, is discharged according to a specific data signal (D), wherein the data signal controls only transistors of a single type (either only N-channel or only P-channel). The master latch circuit (10) has only one supply voltage.

Master latch circuit with signal level displacement for a dynamic flip flop

The invention relates to a master latch circuit with signal level displacement for a dynamic flip flop which has a minimal signal switching delay.

U.S. Pat. No. 6,507,228 B2 describes a clock edge triggered latch circuit suitable for a high-frequency clock signal. The latch circuit contains a signal delay circuit, which delays the clock signal present by a specific time. A circuit node connected downstream is charged depending on a data signal present during a time window that is adjustable by means of the delay time.

In digital systems, the computing power is limited on account of the heating of the digital system as a result of the power loss that occurs. Furthermore, the power loss of the components limits the operating duration particularly in the case of mobile digital systems.

It has been proposed, therefore, to use a plurality of operating voltages within a digital logic block, a high operating voltage being made available for the components in the case of the critical signal paths, while the components are supplied with a low supply voltage in the case of the noncritical signal paths. The dynamic losses, in particular, which depend quadratically on the operating voltage, are reduced as a result of the low supply voltage. However, the use of a plurality of operating voltages gives rise to the problem area that there are signal transitions between different voltage domains on account of the logical structure of the circuit. What is critical in this case is, in particular, the signal transition from a region with a low supply voltage to a region with a high supply voltage.

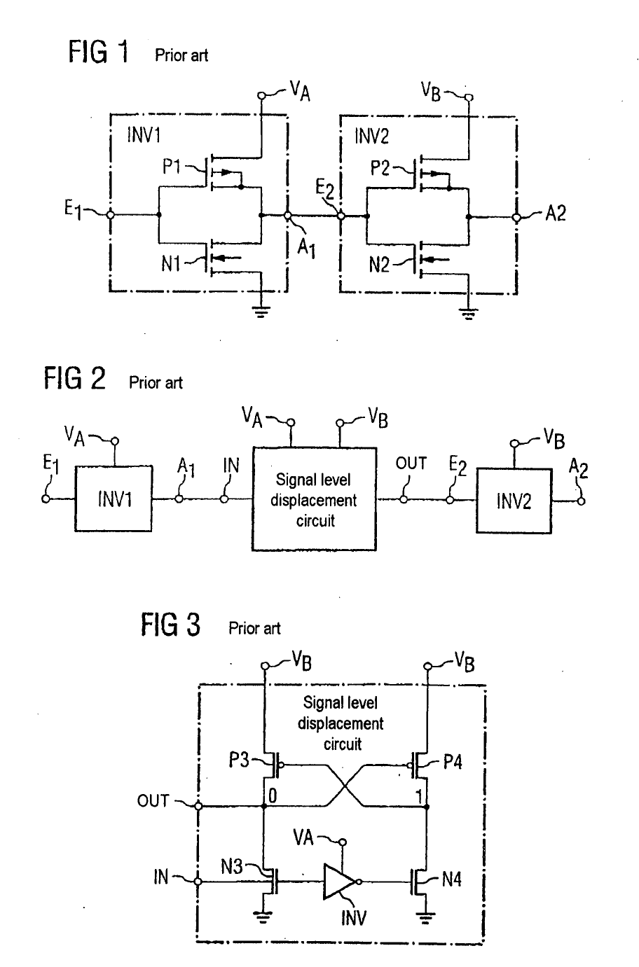

FIG. 1 shows the transition between a first digital system, which is supplied with a relatively low supply voltage V_{A}, to a second digital system, which is supplied with a higher supply voltage V_{B}. If the inverter INV₁ of the first digital system outputs a logical zero or a low signal level via the output A₁ to the input E₂ of the inverter INV₂ of the second digital system with a high supply voltage V_{B}, the N-channel transistor N₂ is turned off and the P-channel transistor P₂ is opened, so that a digital output signal with a high logical signal level is output by the output A₂. In this case, the signal level swing at the output A₂ essentially corresponds to the high operating voltage V_{B}. If a logically high signal level corresponding to the low supply voltage V_{A} is present at the output A₁ of the first digital system, the N-channel transistor N₂ is opened. However, the P-channel transistor P₂ does not turn off completely in this case, so that a shunt current or short-circuit current flows. The power loss brought about by said short-circuit current partly compensates for the reduction of the power loss on account of the use of a plurality of operating voltages V_{A}, V_{B} and even has the effect that the power loss rises overall. A further problem is that the output level is possibly logically undefined on account of the shunt current.

Therefore, in order to avoid the shunt currents, use is made of a signal level displacement circuit according to the prior art such as is illustrated in FIG. 2. The signal level displacement circuit leads to a conversion of the low voltage level swing at the inverter stage INV₁ to a high voltage level swing at the inverter stage INV₂.

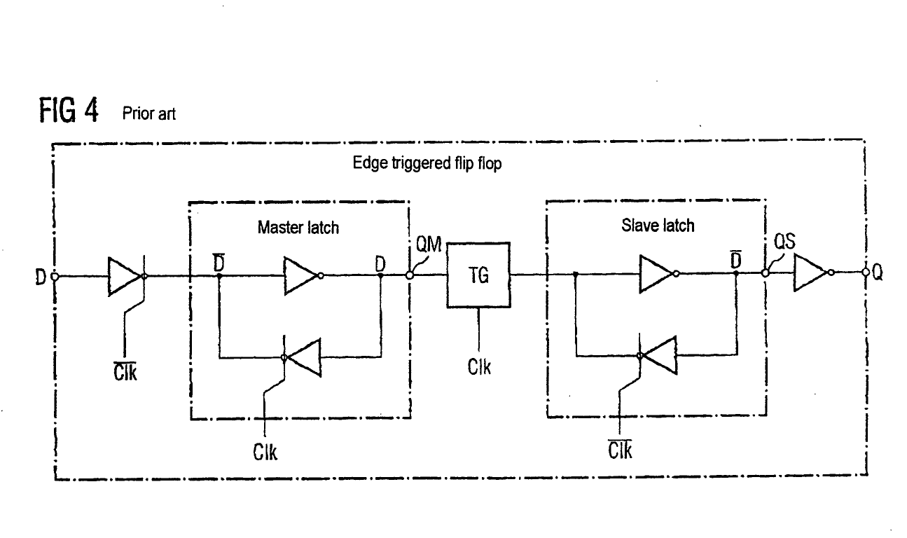

FIG. 3 shows the circuitry construction of the signal level displacement circuit according to the prior art. The signal level displacement circuit contains two cross-coupled PMOS transistors that are supplied with the high operating voltage V_{B}. The input signal originating from the inverter stage INV₁ with a low operating voltage V_{A} is applied to a first NMOS transistor N₃ and, via an inverter INV, to a second NMOS transistor N₄. If the inverter stage INV₁ outputs a logically high signal, the NMOS transistor N₃ turns on, and the NMOS transistor N₄ is turned off. If the inverter stage INV₁ outputs a logically low signal, the NMOS transistor N₃ turns off and the NMOS transistor N₄ turns on. As a result of the positive feedback, a logically high signal whose signal level essentially corresponds to the high operating voltage V_{B} is generated at the output of the signal level displacement circuit.

The signal level displacement circuit as illustrated in FIG. 3 avoids the shunt current that occur in the case of direct coupling of the two voltage domains as occur in the case of the circuit arrangement illustrated in FIG. 1.

However, the signal level displacement circuit according to the prior art such as is illustrated in FIG. 3 has a few disadvantages. Since the inverter INV contained therein is supplied with the low supply voltage V_{A} and the two PMOS transistors P₃, P₄ with the high supply voltage V_{B}, the corresponding components within the signal level displacement circuit have to comply with a specific minimum distance in accordance with the ESD design rules (ESD: electrostatic discharge). This has the effect that the signal level displacement circuit requires a relatively high area in the case of integration on a chip.

A further disadvantage consists in the fact that the signal level displacement circuit of FIG. 3 leads to a signal delay within the signal path, so that the computing power of the entire digital system decreases.

A further disadvantage consists in the fact that the signal level displacement circuit in accordance with FIG. 3 has a specific inherent power loss, so that the total power loss of the circuit increases.

In order to minimize the disadvantages mentioned, it is proposed, therefore, to integrate the signal level displacement function into an edge triggered flip flop. FIG. 4 shows an edge triggered flip flop according to the prior art without signal level displacement. The edge triggered flip flop contains a master latch circuit and a slave latch circuit, which are isolated from one another by a transmission gate TG or an isolating circuit. The isolating circuit TG is clocked by a clock signal Clk. The edge triggered flip flop has a data signal input D, which is connected to the master latch circuit via an inverter stage with a transmission gate connected downstream. The data signal D present is written to the master latch circuit during a low level of the clock signal Clk. At the same time, the master latch circuit and the slave latch circuit are isolated from one another by the transmission gate TG. The master latch circuit is transparent, that is to say that the transmission gate TG provided in the feedback path of the master latch circuit turns off, so that the feedback loop is interrupted. The last datum written in is held in the slave latch circuit and is present at the output of the edge triggered flip flop. The last datum D is present at the output Q_{M} of the transparent master latch circuit. Upon the next rising edge of the clock signal Clk, the feedback loop within the master latch circuit is closed in order to buffer-store the last datum D. The master latch circuit and the slave latch circuit are connected to one another by the transmission gate TG, and the slave latch circuit is switched to transparent, that is to say that the feedback loop within the slave latch circuit is interrupted. The datum present at the output Q_{M} of the master latch circuit is thus transferred into the transparent slave latch circuit and is present at the output A_{S} of the slave latch circuit. Upon the next falling edge, the master latch circuit is isolated from the slave latch circuit again and the feedback loop within the slave latch circuit is closed for the purpose of buffer-storing the datum. The master latch circuit is then transparent for the purpose of reading in a new datum D.

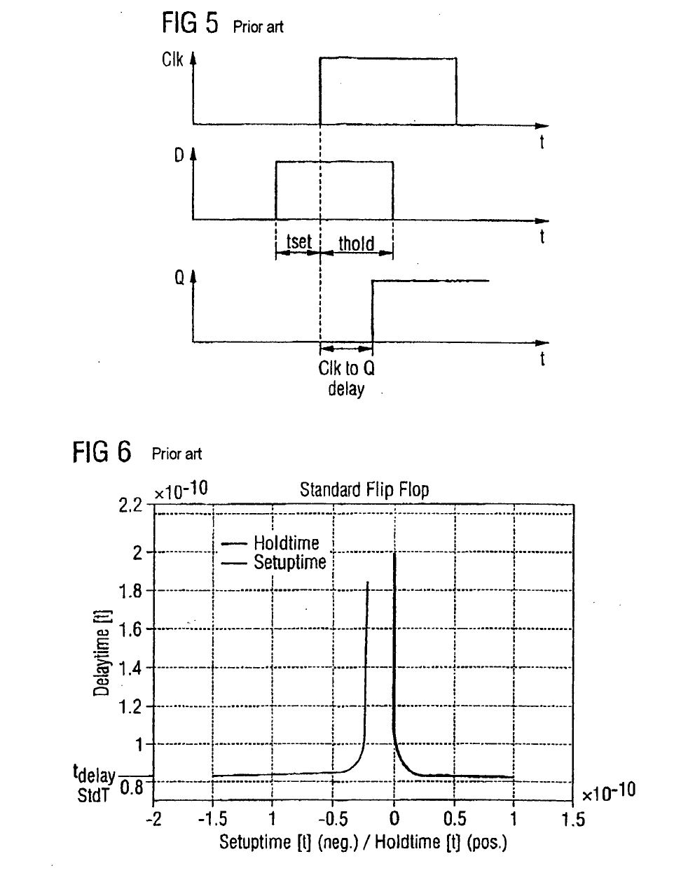

FIG. 5 shows by way of example the set-up time tₛₑₜ and the hold time t_{hold} of the edge triggered flip flop according to the prior art as illustrated in FIG. 4. One essential property of the edge triggered flip flop is the delay time caused by the flip flop, in particular the delay time between the rising clock edge of the clock signal Clk and the validity of the datum Q at the output of the flip flop, the so-called clock-to-Q delay time. The set-up and hold times specify how long before and how long after the clock signal the input signal D must be valid in order to comply with a specific clock-to-Q delay time.

FIG. 6 shows by way of example for one technology the time behavior of the flip flop according to the prior art as illustrated in FIG. 4. The delay time lies somewhat above 0.8×10⁻¹⁰ seconds in the normal operating range.

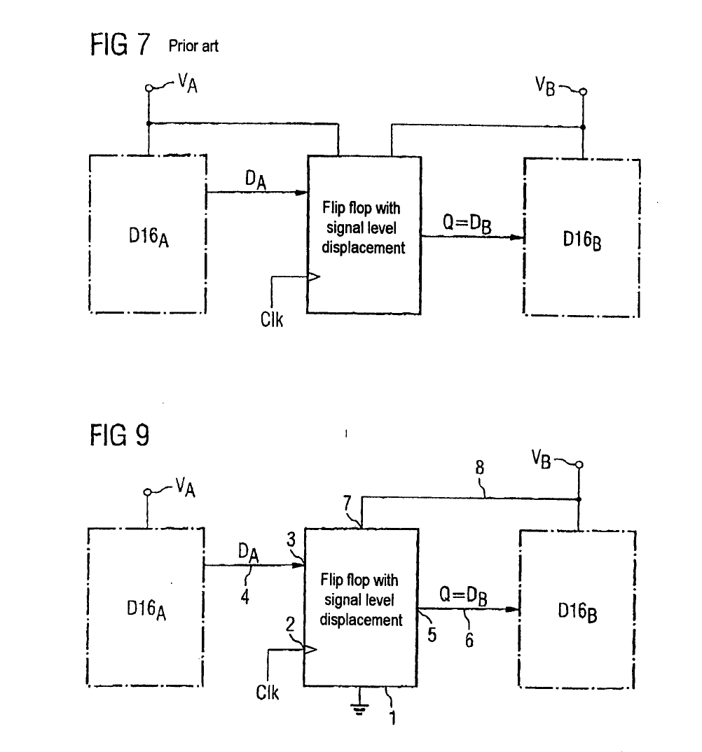

In order to avoid the disadvantages associated with a conventional signal level displacement circuit such as is illustrated in FIG. 3, a static flip flop with signal level displacement has been proposed according to the prior art, as is illustrated in FIG. 7. A dynamic flip flop with signal level displacement is provided between a first digital data processing system DIG_{A}, which is supplied with a relatively low supply voltage V_{A}, and a second digital system DIG_{B}, which is supplied with a relatively high supply voltage V_{B}. The flip flop is clocked with a clock signal Clk and converts the incoming data signal D_{A} with a low signal level swing into an output data signal D_{B} with a high signal level swing.

FIG. 8 shows the conventional static flip flop with signal level displacement according to the prior art in detail. In the case of the flip flop with signal level displacement, the slave latch circuit is altered in terms of circuitry in comparison with a conventional edge triggered flip flop such as is illustrated in FIG. 4. The output of the master latch circuit is connected to the slave latch circuit via a first transmission gate TG₁. The input of the master latch circuit is connected to the slave latch circuit in each case via a second transmission gate TG2. The data signal D_{A} with a low signal level that is written to the master latch circuit and the complementary data signal \overline{D}_{A} with respect thereto are applied to the gate terminals of two NMOS transistors N₅, N₆ via the two transmission gates TG₁, TG₂. If the data signal D_{A} with a low signal level swing is logically high, the NMOS transistor N₆ turns on and the NMOS transistor N₅ turns off. A logically low data value \overline{D}_{B} is then present at the output Q_{S} of the slave latch circuit. Conversely, if the data signal D_{A} is logically low, the NMOS transistor N₆ turns off and the NMOS transistor N₅ turns on. As a result of this, a logically high datum having a high signal level corresponding to the high supply voltage V_{B} is present at the output Q_{S} of the slave latch circuit.

By virtue of the integration of the signal level displacement into the conventional static flip flop, as illustrated in FIG. 8, although it is possible overall to save somewhat on chip area and power loss in comparison with a conventionally edge triggered flip flop, as illustrated in FIG. 4, and a conventional signal level displacement circuit, as illustrated in FIG. 3, the signal delay nonetheless still results essentially from the sum of the signal delay of the signal level displacement circuit and the signal delay caused by the flip flop.

Since the flip flop with signal displacement according to the prior art as illustrated in FIG. 7 and FIG. 8 likewise has to be supplied with two supply voltages V_{A}, V_{B}, it is necessary, moreover, to comply with specific minimum distances between the components, so that the area saving is relatively small and the signal delay is relatively large.

Therefore, the object of the present invention is to provide a master latch circuit with signal level displacement for a dynamic flip flop which has a minimal signal delay.

This object is achieved according to the invention by means of a master latch circuit having the features specified in patent claim 1.

The invention provides a master latch circuit with signal level displacement for a flip flop which is clocked by a clock signal (Clk), the master latch circuit having:

a signal delay circuit, which delays and inverts the clock signal (Clk) present with a specific time delay (ΔT); and

a circuit node which, in a charging phase, in which the clock signal (Clk) present is logically low, is charged to an operating voltage (V_{B}) and which, in an evaluation phase, if the clock signal (Clk) present and the delayed inverted clock signal (Clk_{DELAY}) are logically high, can be discharged depending on a data signal (D) present.

The input signal from the low voltage domain Vₐ drives only transistors of one type in this case (either only P-channel or only N-channel).

The master latch circuit with signal level displacement for a dynamic flip flop according to the invention has the advantage that the dynamic flip flop only has to be supplied with one operating voltage.

As a result of this, the components of the dynamic flip flop can be arranged at a very small distance from one another on the chip. This has the effect that the master latch circuit according to the invention or the dynamic flip flop can be integrated with a minimal area requirement on the chip.

Moreover, signal propagation times within the master latch circuit according to the invention or the dynamic flip flop according to the invention are minimized on account of the components being spaced apart minimally.

A further advantage of the master latch circuit according to the invention consists in the fact that a minimal number of circuitry components are integrated therein, so that the power loss of the master latch circuit according to the invention is likewise minimized.

In one preferred embodiment of the master latch circuit according to the invention, the circuit node (LDN) is discharged in the evaluation phase if the data signal (D) present is logically high, and the circuit node (LDN) is not discharged in the evaluation phase if the data signal (D) present is logically low.

In one preferred embodiment, the circuit node (LDN) is connected to a reference potential (GND) via a capacitance (C).

In a first embodiment, said capacitance (C) is a parasitic capacitance.

In an alternative embodiment, the capacitance (C) is formed by a capacitor provided.

In one preferred embodiment of the master latch circuit according to the invention, the circuit node (LND) is connected to an input of a first isolating circuit clocked by the clock signal (Clk).

The first isolating circuit preferably has an output connected to a slave latch circuit, which buffer-stores the output signal of the master latch circuit.

An inverter is preferably connected downstream of the slave latch circuit.

In one preferred embodiment, the output of the first isolating circuit is fed back to the input of the first isolating circuit via a second clocked isolating circuit, the second isolating circuit being clocked with the delayed clock signal (Clk_{DELAY}).

The provision of the second clocked isolating circuit has the advantage that, after the evaluation phase, the charge at the circuit node (LDN) is held actively at a specific signal level by means of the feedback.

A decrease in the signal level at the circuit node (LDN) for example on account of leakage currents or noise can thereby be prevented.

In a further embodiment of the master latch circuit according to the invention, the master latch circuit has a first controllable switch, which is driven by the inverted clock signal (\overline{Clk}) and which switches the operating voltage (V_{B}) present to the circuit node (LDN) if the clock signal (Clk) is logically low.

The first controllable switch is preferably a PMOS transistor.

In one preferred embodiment of the master latch circuit according to the invention, the master latch circuit has a second controllable switch, a third controllable switch, and a fourth controllable switch, which are connected in series with one another between the circuit node (LDN) and the reference potential (GND).

In this case, the second controllable switch is preferably driven by the delayed inverted clock signal (\overline{CLK_{DELAY}})

The third controllable switch is preferably driven by the data signal (D) present.

The fourth controllable switch is preferably driven by the clock signal (Clk).

The second, third and fourth controllable switches are preferably NMOS transistors.

The second, third and fourth controllable switches are preferably connected in parallel with the capacitance.

In one particularly preferred embodiment of the master latch circuit according to the invention, the time delay (ΔT) of the signal delay circuit is adjustable.

In this case, the time constant (τ) with which the capacitance (C) is discharged via the series-connected switches during the evaluation phase if the data signal (D) present is logically high is less than the time delay (ΔT) of the signal delay circuit (τ<<ΔT).

The time delay (ΔT) of the signal delay circuit is preferably substantially less than the time period of the clock signal (Clk) (ΔT<<T_{clk}).

In one preferred embodiment, the signal delay circuit is formed by a plurality of inverter stages connected in series.

The invention furthermore provides an edge triggered flip flop with a master latch circuit according to claim 1, with a slave latch circuit for buffer-storing the output signal of the master latch circuit and with a clocked isolating circuit for isolating the master latch circuit from the slave latch circuit.

The invention provides a dynamic flip flop with signal level displacement, which has:

a master latch circuit having a signal delay circuit, which delays and inverts the clock signal present with a specific time delay (ΔT);

a circuit node which, in a charging phase, in which the clock signal (Clk) present is logically low, is charged to an operating voltage and which, in an evaluation phase, if the clock signal (Clk) present and the delayed inverted clock signal (Clk_{DELAY}) are logically high, can be discharged depending on a data signal (D) present; a slave latch circuit for buffer-storing the output signal of the master latch circuit; and having a clocked isolating circuit for isolating the master latch circuit from the slave latch circuit.

In this case, the input signal D drives only transistors of a single type (either only N-channel or only P-channel).

Preferred embodiments of the master latch circuit with signal level displacement for a dynamic flip flop according to the invention are described below with reference to the accompanying figures for elucidating features that are essential to the invention.

In the figures:

FIG. 1 shows two coupled digital systems with different operating voltages according to the prior art;

FIG. 2 shows the coupling of two digital systems with different operating voltages by means of a signal level displacement circuit according to the prior art;

FIG. 3 shows a circuitry construction of a signal level displacement circuit according to the prior art;

FIG. 4 shows an edge triggered flip flop according to the prior art;

FIG. 5 shows a diagram for elucidating the delay time in the case of a conventional edge triggered flip flop according to the prior art;

FIG. 6 shows the time behavior of a conventional flip flop according to the prior art;

FIG. 7 shows a flip flop with integrated signal level displacement for coupling two digital systems with a different operating voltage according to the prior art;

FIG. 8 shows the circuitry construction of a static flip flop with integrated signal level displacement according to the prior art;

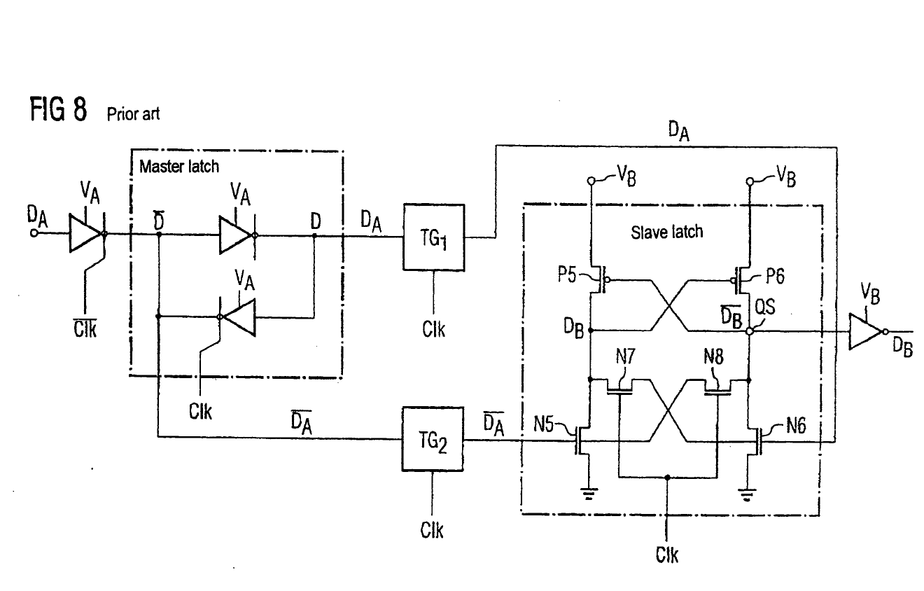

FIG. 9 shows a dynamic flip flop according to the invention with integrated signal level displacement for coupling two digital systems in accordance with the invention;

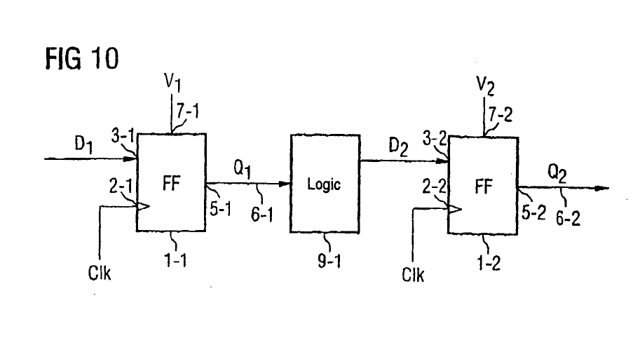

FIG. 10 shows a register transfer logic with a plurality of flip flops according to the invention with integrated signal level displacement;

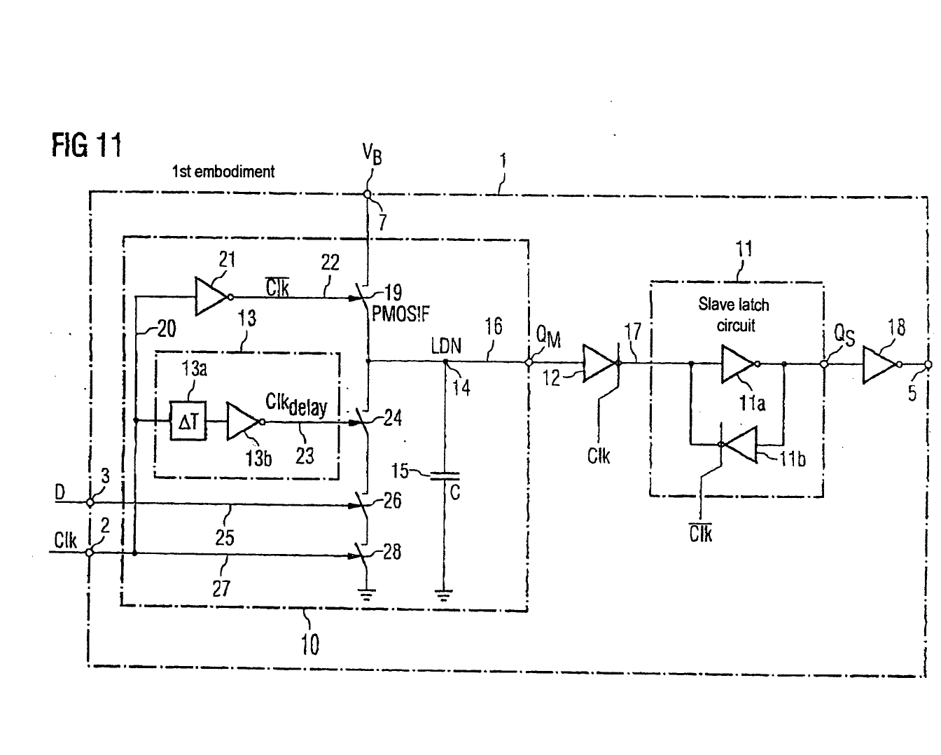

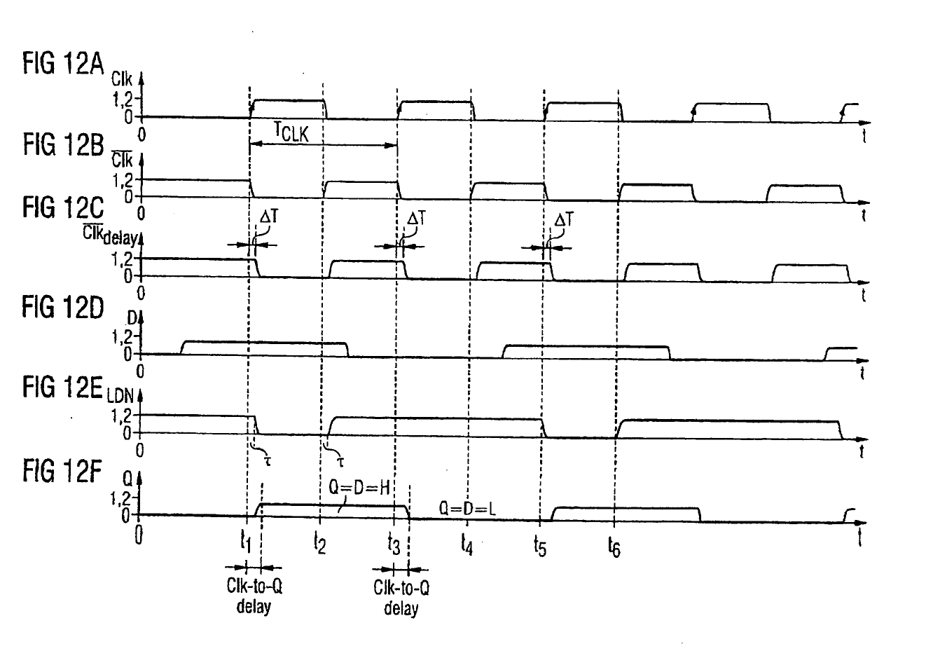

FIG. 11 shows the circuitry construction of a first embodiment of the master latch circuit according to the invention with signal level displacement;

FIG. 12 shows a timing diagram for elucidating the functioning of the master latch circuit according to the invention;

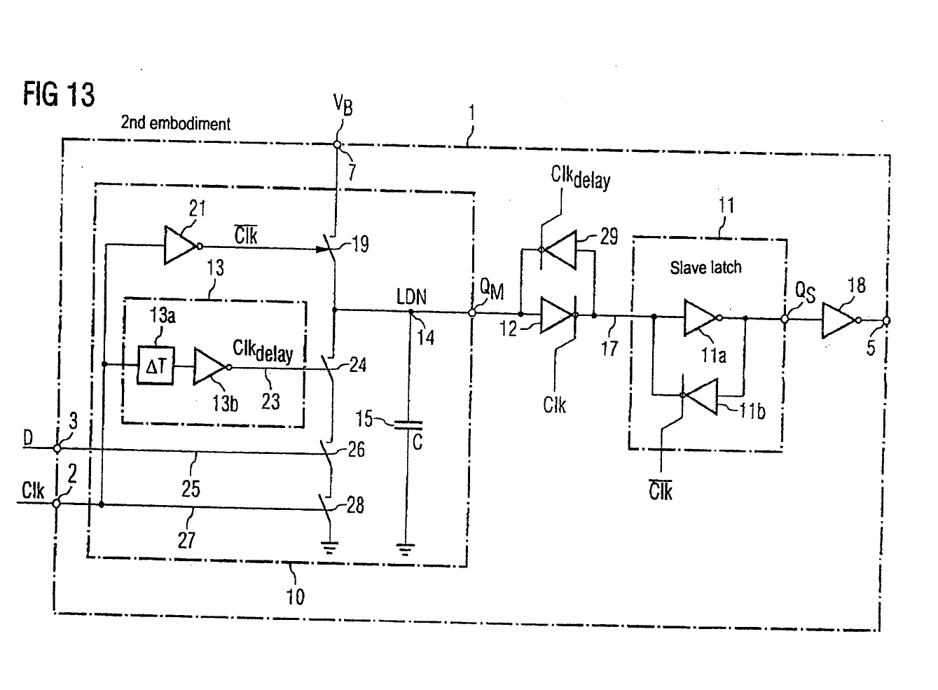

FIG. 13 shows the circuitry construction of a second embodiment of the master latch circuit according to the invention;

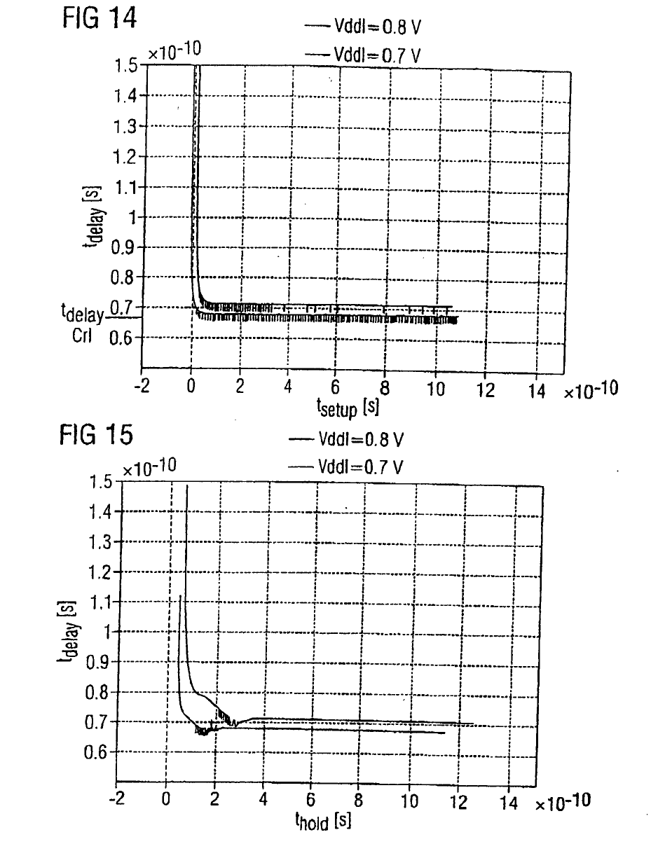

FIG. 14 shows a diagram of the time behaviour of the master latch circuit according to the invention by way of example for a technology in accordance with the second embodiment as a function of the set-up time;

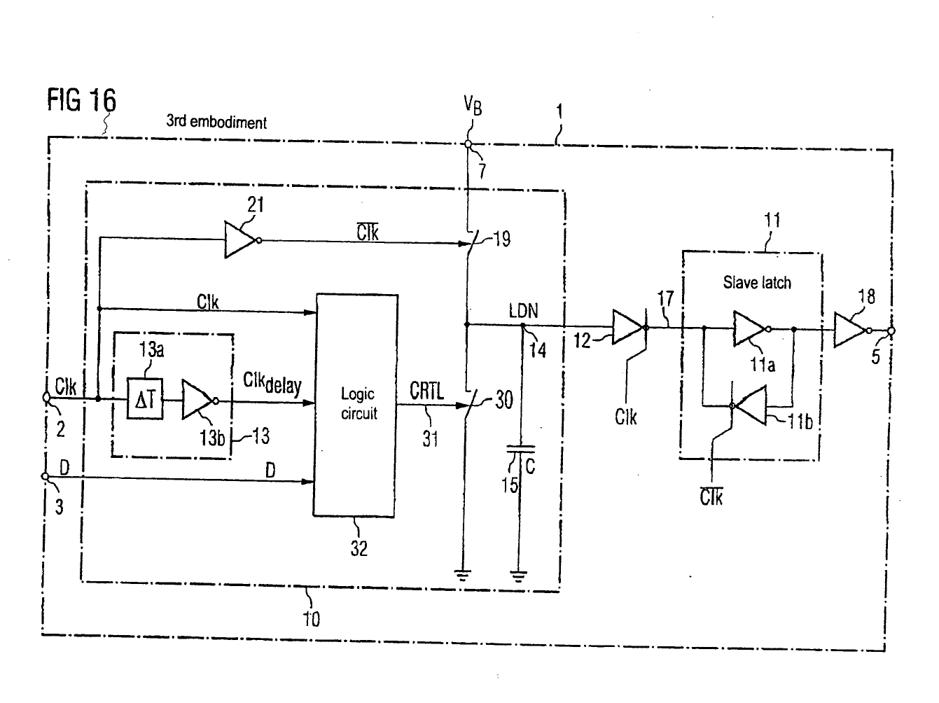

FIG. 15 shows a diagram of the time behavior of the master latch circuit according to the invention in accordance with the second embodiment as a function of the hold time;

FIG. 16 shows the circuitry construction of a third embodiment of the master latch circuit according to the invention for a dynamic flip flop.

FIG. 9 shows a dynamic flip flop 1 in accordance with the invention for coupling a first digital system DIG_{A} with a low supply voltage V_{A} and a second digital system DIG_{B} with a relatively high supply voltage U_{B}. The dynamic flip flop with integrated signal level displacement 1 has a clock signal input 2 for application of a clock signal Clk and a data signal input 3 for receiving a data signal D_{A} from the first digital system DIG_{A}. The data signal D_{A} received from a line 4 has a relatively low signal level swing corresponding to the relatively low supply voltage V_{A}. The dynamic flip flop 1 according to the invention has a data output 5, which outputs an output datum Q=D_{B} via an output signal line 6 to the second digital system DIG_{B}, which is supplied with a relatively high supply voltage V_{B}. The datum D_{B} that is output has a high signal level swing corresponding to the second supply voltage V_{B}. The dynamic flip flop 1 additionally utilizes a voltage supply terminal 7, which is connected to the high supply voltage V_{B} of the second digital system DIG_{B} via a line 8. As can be discerned from FIG. 9, the dynamic flip flop 1 according to the invention, which contains the master latch circuit according to the invention, is only supplied by one supply voltage V_{B}. This affords the advantage that the distances between the components within the dynamic flip flop 1 can be kept minimal without violating the ESD design rules. The area requirement of the dynamic flip flop 1 according to the invention is correspondingly small. Moreover, the dynamic flip flop according to the invention enables a reduced outlay in the context of positioning and wiring since only one supply voltage has to be routed to the circuit.

FIG. 10 shows a register transfer logic containing a plurality of dynamic flip flops for signal level displacement 1-1, 1-2. The digital logic comprising a multiplicity of gates is situated between the dynamic flip flops 1 according to the invention. The operating clock frequency f_{clk} of the register transfer logic is determined by the sum of the signal delay time of the flip flops 1-i and the interposed logic circuits 9-i. The dynamic flip flops 1-i according to the invention have a minimal signal delay time, so that the sum of the signal delay times within the register transfer logic is likewise minimized. The operating clock frequency f_{Clk} of the entire register transfer logic is increased as a result of this, so that the computer power of the entire digital system is considerably increased.

FIG. 11 shows a first embodiment of a dynamic flip-flip 1 according to the invention. The dynamic edge triggered flip flop 1 contains a master latch circuit 10 according to the invention, a slave latch circuit 11 and an interposed clocked isolating circuit or a transmission gate 12. The clocked isolating circuit 12 may comprise e.g. an inverter stage with transmission gate connected downstream, which is clocked by the clock signal Clk.

The master latch circuit 10 comprises a signal delay circuit 13, which delays and inverts the clock signal Clk present at the clock signal input with a specific time delay ΔT. In this case, the signal delay circuit 13 preferably comprises a series of series-connected inverter stages 13a, which brings about a specific time delay ΔT, and an inverter 13 being connected downstream. The master latch circuit 10 contains a dynamic circuit node 14 which, in a charging phase, if the clock signal (Clk) present is logically low, is charged to an operating voltage V_{B} present at the terminal 7 and which, in an evaluation phase, if the clock signal (Clk) present and the delayed inverted clock signal that is output by the signal delay circuit 13 are logically high, can be discharged depending on the data signal (D) present at the terminal 3. The circuit node 14 is discharged in the evaluation phase if the data signal (D) present is logically high, and conversely the circuit node 14 is not discharged during the evaluation phase if the data signal (D) present is logically low.

In an alternative embodiment, the master latch circuit 10 may be constructed complementarily with respect to the circuit illustrated in FIG. 11.

The circuit node 14 is connected to a reference potential via a capacitance 15. The reference potential is preferably ground (GND). In a first embodiment of the master latch circuit 10 according to the invention, the capacitance 15 is formed by a parasitic capacitance C.

In an alternative embodiment, the capacitance C is formed by at least one capacitor provided.

As an alternative, the capacitance C may be formed by a programmable capacitor network, which permits programming of the time constant T for the charging and discharging of the circuit node 14.

The circuit node 14 is connected via a line 16 to an input of the first isolating circuit 12, which is clocked by the clock signal Clk for driving the transmission gate contained therein. The output of the first isolating circuit 12 is connected via a line 17 to an input of the slave latch circuit 11, which buffer-stores the output signal Q_{M} of the master latch circuit 10. An inverter 18 is preferably connected downstream of the slave latch circuit 11, which inverter inverts the output signal Q_{S} of the slave latch circuit 11 and outputs the output signal Q of the dynamic flip flop 1 at the output 5 of the flip flop 1.

The master latch circuit 10 has a first controllable switch 19, which is driven by the inverted clock signal (\overline{Clk}). The clock signal input 2 of the flip flop 1 is connected via a line 20 to an inverter 21 for inverting the clock signal Clk. However, the inverter may be omitted if a corresponding type of transistor (here P-channel) is used for the switch 19. The output of the inverter 21 is connected to the control input of the switch 19 via a line 22. The controllable switch 19 is preferably a PMOS transistor. If the clock signal Clk is logically low, the PMOS transistor 19 turns on and connects the operating voltage terminal 7 to the dynamic node 14, so that the latter is charged to the operating voltage V_{B} during the charging phase.

The signal delay circuit 13 is connected, on the output side, via a line 23 to a second controllable switch 24, which is preferably an NMOS transistor.

The data signal D present at the data signal input 3 is applied via a line 25 directly to the control input of a further controllable switch 26, which is likewise preferably an NMOS transistor. The clock signal Clk present at the clock signal input 2 controls a third controllable switch 28, which is preferably likewise implemented as an NMOS transistor, via an internal line 27. The NMOS transistors 24, 26, 28 are connected in series with one another. In this case, they are connected up in series between the dynamic circuit node 14 and the reference potential GND.

The series circuit of the three NMOS transistors 24, 26, 28 is connected up in parallel with the capacitance 15 present.

In the charging phase, the capacitance 15 is via the PMOS transistor 19 with a specific time constant τ_{charging} resulting from the product of the capacitance of the capacitor 15 and the switch-over resistance Rₛ₁ of the PMOS transistor:
τ_{charging}=R₁₉·C₁₅ (1)

In the evaluation phase, the dynamic circuit node 14, in a specific time window if the clock signal Clk present and the delayed inverted clock signal (\overline{Clk_{DELAY}}) are logically high, depending on the data signal D present, is discharged if the data signal D is logically high and is not discharged if the data signal D is logically low. The time window is determined by the time delay ΔT of the signal delay circuit 13. In this case, the delay time AT is preferably adjustable.

The discharging of the dynamic node 14 for the case where the data signal present is logically high within the time window is effected with a discharge time constant τ_{discharge} determined by the product of the on resistances of the series-connected NMOS transistors 24, 26, 28 and the capacitance of the capacitor 15:
τ_{discharge}=(R₂₄+R₂₆+R₂₈)·C₁₅ (2)

The signal delay time ΔT of the signal delay circuit 13 is chosen such that it is considerably greater than the discharge time constant τ_{discharge}
ΔT>>τ_{discharge} (3)

Furthermore, it must be ensured that the signal delay time ΔT of the signal delay circuit 13 is considerably less than the clock period T_{clk} of the clock signal Clk present.
ΔT<<<T_{Clk} (4)

The data signal Q_{M} present at the dynamic circuit node 14 is buffer-stored in the slave latch circuit 11 connected downstream. The slave latch circuit 11 contains an inverter 11a, the output of which is fed back via an isolating circuit 11b via the input of the inverter 11a. The isolating circuit 11b contains an inverter with an integrated transmission gate which is driven by the inverted clock signal \overline{Clk}.

FIGS. 12a-12f show signal sequences for elucidating the functioning of the flip flop 1 according to the invention with integrated signal level displacement.

FIG. 12a shows the signal profile at the clock signal input 2 of the dynamic flip flop 1.

FIG. 12b shows the clock signal \overline{Clk} inverted at the inverter.

FIG. 12c shows the inverted clock signal \overline{Clk_{DELAY}} that is signal-delayed by the signal delay circuit 13 and drives the NMOS transistor 24.

FIG. 12d shows by way of example a data signal D present at the data signal input 3.

FIG. 12e shows the associated signal profile at the dynamic circuit node LDN (Logic Decision Node).

FIG. 12f shows the signal profile at the signal output 5 of the dynamic flip flop 1 according to the invention.

At the instant t₁, the clock signal Clk has a rising signal edge, so that the NMOS transistor 28 turns on. The NMOS transistor 24 is also still turned on within a time window determined by the signal delay time AT of the signal delay circuit 13.

During the time window ΔT, the data signal D is logically high, so that the NMOS transistor 26 concurrently connected in series is also turned on. The logic decision mode (LDN) 14 is discharged via the series-connected NMOS transistors 24, 26, 28 with the discharge time constant τ_{discharge}. It can be seen in FIG. 12e that the node 14 is discharged during the time window ΔT.

At the instant t₂, the clock signal Clk has a falling signal edge, so that the NMOS transistor 28 is turned off. At the same time, the PMOS transistor 19 turns on, so that the dynamic circuit node 14 is charged to the operating voltage V_{B} with a charging time constant τ_{charging}. The circuit node 14 remains charged until the next time window at the instant t₃. At the instant t₃, a time window is opened again in order to close the two NMOS transistors 24, 28. In the example illustrated, the data signal D is logically low at this instant, so that the NMOS transistor 26 remains open and, consequently, the capacitor 15 is not discharged. At the instant t₅, a time window AT is opened again, the circuit node 14 being correspondingly discharged on account of the logically high data signal D.

As can be discerned from FIG. 11, the signal delay time of the flip flop 1 according to the invention, i.e. the signal delay between the rising signal edge of the clock signal Clk and the instant at which the data signal is present at the output 5 of the flip flop 1, is very low. In this case, the signal delay time is significantly lower than the sum of the signal delay times on a conventional flip flop with a standard signal level displacement circuit such as is illustrated in FIG. 3.

A further advantage of the first embodiment of the flip flop 1 according to the invention or the master latch circuit 10 according to the invention as illustrated in FIG. 11 consists in the fact that only one supply voltage V_{B} has to be provided. The spacing apart of the components can therefore be correspondingly small, so that the area requirement of the flip flop 1 according to the invention in the case of integration on a chip is likewise small. The provision of just one supply voltage V_{B} for supplying the flip flop 1 according to the invention furthermore leads to a minimization of the circuitry outlay for the wiring of the flip flop with the supply voltage.

In an alternative embodiment of the master latch circuit 10, the controllable switch 24 is a PMOS transistor and the controllable switches 26, 28 are formed by NMOS transistors. The advantage of this embodiment consists in the fact that an inversion of the delayed clock signal Clk_{DELAY} is not necessary, so that the inverter 13b is omitted.

The dynamic flip flop 1 according to the invention generally carries out a signal level boosting of the data signal present.

As an alternative, the flip flop according to the invention may also bring about a signal level lowering of the data signal present for data systems connected downstream. The logic decision node 14 stores the supplied data information during half a clock phase T_{Clk}/2. As a result of this, the dynamic flip flop 1 according to the invention becomes particularly fast and takes up only a small area in this case.

FIG. 13 shows a second embodiment of the dynamic flip flop 1 according to the invention.

In the case of the embodiment illustrated in FIG. 13, the output 17 of the first isolating circuit 12 is fed back to the input of the first isolating circuit 12 via a second clocked isolating circuit 29. In this case, the second isolating circuit 29 contains an inverter and a transmission gate connected downstream, which is clocked with the delayed clock signal Clk_{DELAY}. What is achieved by providing the second isolating circuit 29 is that the charge at the circuit node 14 is actively held at the present voltage level. If a high voltage level is present at the circuit node 14, it can happen that the voltage at this circuit node 14 decreases as a result of leakage currents or interference signals. What is achieved by virtue of the feedback by means of the isolating circuit 29 is that the charge is actively held at the high voltage level. The logic decision node 14 stores the data information only during the transparency window ΔT, that is to say as long as the input signal is being read in. No feedback by means of the isolating circuit 29 is effected during the read-in phase.

FIG. 14 shows the signal delay of the dynamic flip flop according to the invention in accordance with the second embodiment, as illustrated in FIG. 13, as a function of the set-up time for two different input voltage levels. As can be discerned by comparing FIG. 14 with FIG. 6, the signal delay time of the dynamic flip flop 1 according to the invention in accordance with the second embodiment is less than the signal delay time of a conventional standard flip flop.

FIG. 15 shows the dependence of the signal delay of the dynamic flip flop 1 according to the invention in accordance with the second embodiment, as illustrated in FIG. 13, for various hold times for three different input voltage levels. As can be discerned by comparison with FIG. 6, the signal delay of the flip flop 1 according to the invention is lower compared with a standard flip flop.

FIG. 16 shows a third embodiment of the master latch circuit 10 according to the invention. In the case of the third embodiment illustrated in FIG. 16, the master latch circuit 10 no longer has three series-connected NMOS transistors 24, 26, 28, but rather only one NMOS transistor 30, which is driven by a logic circuit 32 via a control line 31. The logic circuit 32 logically combines the clock signal Clk present at the clock signal input 2, the data signal D present at the data signal input 3, and the clock signal Clk_{DELAY} that has been delayed and inverted by the signal delay circuit 13. If the clock signal Clk present and the delayed inverted clock signal \overline{Clk_{DELAY}} and also the data signal D present are all logically high, the NMOS transistor 30 is turned on by the logic circuit 32, so that the capacitance 15 is discharged in the evaluation phase. In this embodiment, the logical circuit 32 comprises a logical ANDing of the three signals present.

The dynamic flip flops 1 according to the invention such as have been illustrated in FIGS. 11, 13, 16 have a very low signal delay time. If a complex digital system has a plurality of signal paths running parallel, the longest signal path forms a critical signal path. The time-critical signal path is supplied with voltage with a high supply voltage V_{B}. The remaining signal paths, in order to save energy, are supplied with voltage with a relatively low supply voltage V_{A}. In order that a high voltage level is likewise present at the output of the noncritical signal paths supplied with low voltage, flip flops with an integrated signal level displacement function are used within the noncritical signal paths, as is illustrated for example in FIG. 8. If a noncritical path has only a slightly shorter signal delay than the critical signal path, such a flip flop with integrated signal level boosting cannot be used according to the prior art since, on account of the relatively high signal propagation time delay of the flip flop, the signal propagation time of the noncritical signal path lies above the total signal propagation time of the critical signal path in the case where the flip flop is used.

The dynamic flip flop 1 according to the invention makes it possible also for time-noncritical signal paths whose signal propagation time is only insignificantly below the signal propagation time of the critical signal path likewise to be provided with a flip flop 1 according to the invention for signal level boosting since the flip flop 1 according to the invention has only a very low signal propagation time and thus increases the signal propagation time of the noncritical signal path only very slightly, so that it still lies below the total signal propagation time of the critical signal path. One advantage of the dynamic flip flop 1 according to the invention for signal level boosting therefore consists in the fact that the number of noncritical signal paths which can be supplied with a low supply voltage V_{A} can be considerably increased.

The dynamic flip flop 1 according to the invention functions for a wide range of input voltages and thereby differs from conventional signal level displacement circuits, which often only permit a narrow voltage range.

The dynamic flip flop 1 according to the invention is distinguished by a low signal delay, a small chip area requirement and a very low power loss.

### LIST OF REFERENCE SYMBOLS

1 Dynamic flip flop
2 Clock signal input
3 Data signal input
4 Line
5 Data output
6 Line
7 Supply voltage terminal
8 Supply voltage line
9 Digital logic
10 Master latch circuit
11 Slave latch circuit
12 Isolating circuit
13 Signal delay circuit
13a Inverter chain
13b Inverter stage
14 Dynamic node
15 Capacitance
16 Line
17 Line
18 Inverter
19 Controllable switch
20 Line
21 Inverter
22 Control line
23 Control line
24 Controllable circuit
25 Control line
26 Controllable circuit
27 Control line
28 Controllable circuit
29 Coupling isolating circuit
30 Controllable switch
31 Control line
32 Logic circuit

1-22. (canceled)

23. A signal level displacement circuit for a flip flop operable to be clocked by a clock signal, the signal level displacement circuit comprising:
a signal delay circuit configured to generate a delayed clock signal corresponding to the clock signal delayed by a time delay;
a circuit node arranged to charge to an operating voltage in a charging phase in response to the clock signal being logically low and to discharge in an evaluation phase depending on a data signal in response to the clock signal being logically high and the delayed clock signal being logically high; and
a capacitor having a programmable capacitance coupling the circuit node to a reference potential.

24. The signal level displacement circuit as claimed in claim 23, wherein the circuit node is arranged to discharge in the evaluation phase in response to the data signal being logically high and the circuit node is arranged to not discharge in the evaluation phase in response to the data signal being logically low.

25. The signal level displacement circuit as claimed in claim 23, further comprising:
a first isolating circuit configured to be clocked by the clock signal and having an input connected to the circuit node.

26. The signal level displacement circuit as claimed in claim 25, further comprising:
a slave latch circuit;
wherein the first isolating circuit has an output connected to the slave latch circuit, the first isolating circuit is configured to generate an output signal at the output, and the slave latch circuit is configured to buffer-store the output signal.

27. The signal level displacement circuit as claimed in claim 25, further comprising:
a second isolating circuit configured and arranged to be clocked by the delayed clock signal;
wherein an output of the first isolating circuit feeds back to the input of the first isolating circuit via the second isolating circuit.

28. The signal level displacement circuit as claimed in claim 23, wherein the signal delay circuit, the circuit node, and the capacitor are incorporated into a master latch circuit.

29. The signal level displacement circuit as claimed in claim 28, wherein:
the master latch circuit further includes an inverter configured to generate and inverted clock signal corresponding to an inversion of the clock signal;
the master latch circuit further includes a first controllable switch driven by the inverted clock signal; and
the first controllable switch switches the operating voltage to the circuit node in response to the clock signal being logically low.

30. The signal level displacement circuit as claimed in claim 28, wherein:
the master latch circuit further includes a reference potential node configured to be coupled to the reference potential;
the master latch circuit further includes a second, third and fourth controllable switchs, the first, second, third, and fourth controllable switches being connected in series with one another between the circuit node and the reference potential node.

31. The signal level displacement circuit as claimed in claim 30, wherein the master latch circuit is configured to generate a delayed inverted clock signal and to drive the second controllable switch with the delayed inverted clock signal.

32. The signal level displacement circuit as claimed in claim 30, wherein the third controllable switch is arranged to be driven by the data signal.

33. The signal level displacement circuit as claimed in claim 30, wherein the fourth controllable switch is arranged to be driven by the clock signal.

34. The signal level displacement circuit as claimed in claim 30, wherein the capacitor is connected in parallel with the second, third and fourth controllable switches.

35. The signal level displacement circuit as claimed in claim 28, wherein the time delay is adjustable.

36. The signal level displacement circuit as claimed in claim 35, wherein during the evaluation phase the capacitor discharges with a time constant in response to the data signal being logically high and the time constant is less than the time delay.

37. The signal level displacement circuit as claimed in claim 28, wherein the master latch circuit is configured to make the time delay is less than a time period of the clock signal.

38. The signal level displacement circuit as claimed in claim 28, wherein the signal delay circuit comprises a plurality of inverter stages connected in series.

39. The signal level displacement circuit as claimed in claim 28, wherein the master latch circuit is configured to receive only a single supply voltage.

40. A method, comprising:
using a clocked isolating circuit to isolate a master latch circuit of an edge triggered flip flop from a slave latch circuit of the flip flop; and
buffer-storing an output signal of the master latch circuit with the slave latch circuit.

41. A flip flop operable to use a data signal and a clock signal, the flip flop comprising:
a signal delay circuit configured to generate a delayed clock signal corresponding to the clock signal delayed by a time delay;
a capacitor configured to generate a programmable capacitance;
a controllable switch operably coupled between the signal delay circuit and the capacitor; and
a master latch circuit incorporating at least one of the signal delay circuit, the capacitor, and the controllable switch;
wherein the master latch circuit is configured to charge the capacitor in response to the clock signal being logically low and the master latch circuit is further configured to discharge the capacitor in response to a combination of the clock signal being logically high, the delayed clock signal being logically high, and a state of the data signal.

42. The flip flop as claimed in claim 24, further comprising:
a slave latch circuit operably coupled to the master latch circuit;
wherein the master latch circuit is further configured to generate an output signal on the capacitor and the slave latch circuit is configured to buffer-store the output signal.
